(19) United States
(12) Patent Application Publication
(10) Pub. No.: US 2007/0087699 A1
(43) Pub. Date: Apr. 19, 2007

(54) SYSTEM AND METHOD FOR TRANSMITTING A SIGNAL BETWEEN INTEGRATED CIRCUITS

(75) Inventors: Han-Che Wang, Shenzhen (CN); Shin-Hong Chung, Shenzhen (CN); Hua-Dong Cheng, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/309,451

(22) Filed: Aug. 9, 2006

(30) Foreign Application Priority Data
Oct. 14, 2005 (CN) 200510100380.7

(51) Int. Cl. H04B 1/40; H04B 17/00; H04B 1/06; H03C 1/62; H04B 7/00

(52) U.S. Cl. 455/75; 455/115.1; 455/255

(57) ABSTRACT

A method for transmitting a signal between ICs is provided. The method provides an apparatus, a first IC, and a second IC. The apparatus is configured with an enclosure. The first IC is configured with an IR emitter. The second IC is configured an IR receiver. The first IC encodes a command into an IR signal. The IR emitter sends the IR signal. The IR receiver receives the IR signal. The second IC decodes the IR signal into the command. Using the method, signal transmission between ICs is wirelessly so as to avoiding difficulties in arranging lines.

### 1. FIELD OF THE INVENTION

The present invention relates to a system and a method for transmitting a signal, particularly to a system and a method for transmitting a signal between integrated circuits.

### 2. DESCRIPTION OF RELATED ART

Integrated circuits (ICs) are in widespread use and are commonly found in many devices. In many instances, signals need to be transmitted between the ICs. If a signal is to be transmitted physically, a number of connections, wires, connectors, buses, would increase proportionately. Furthermore, using physical connections to transmit signals is limited by a number of the ICs, position of the ICs, a number of the IC's stitch, etc.

Therefore, what is needed is a method and a system to transmit a signal between the ICs wirelessly.

### SUMMARY OF THE INVENTION

A system for transmitting a signal between ICs is provided herein. The system includes an apparatus, a first IC, a second IC. The apparatus is configured with an enclosure. The first IC and the second IC are assembled in the apparatus. The first IC is configured with an infrared, below called IR, emitter. The second IC is configured with an IR receiver. The first IC encodes a command into an IR signal. The IR emitter sends the IR signal. The IR receiver receives the IR signal. The second IC decodes the IR signal into the command.

A method for transmitting a signal between ICs is provided herein. The method provides an apparatus, a first IC, and a second IC. The apparatus is configured with an enclosure. The first IC is configured with an IR emitter. The second IC is configured with an IR receiver. The first IC encodes a command into an IR signal. The IR emitter sends the IR signal. The IR receiver receives the IR signal. The second IC decodes the IR signal into the command.

Further features and advantages will be provided or will become apparent in the course of the following detailed description.

### BRIEF DESCRIPTION OF THE DRAWINGS

FIG. 1 is a schematic diagram of a hardware infrastructure of an IC used in a system for transmitting an IR signal;

FIG. 2 is a schematic diagram of a hardware infrastructure of the system for transmitting an IR signal between ICs; and

FIG. 3 is a flow diagram of a preferred method for transmitting an IR signal between ICs, by utilizing the system of FIG. 2.

### DETAILED DESCRIPTION OF THE INVENTION

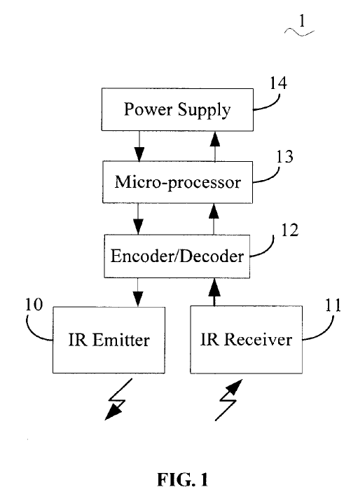

Referring to FIG. 1, shown here is an integrated circuit (IC) for transmitting an infrared (IR) signal. The IC 1 is configured with an IR emitter 10, an IR receiver 11, an encoder/decoder 12, and a micro-processor 13. The micro-processor 13 is connected to the encoder/decoder 12 and a power supply 14. The encoder/decoder 12 is connected to the IR emitter 10 and the IR receiver 11.

If the IC 1 is triggered to send a signal, the micro-processor 13 thereupon generates a command and sends the command to the encoder/decoder 12 to encode the command into an IR signal and to send out the IR signal through the IR emitter 10. If the IC 1 receives the IR signal, the encoder/decoder 12 decodes the IR signal received from the IR receiver 11 into the command and sends the command to the micro-processor 13 which in turn executes the command.

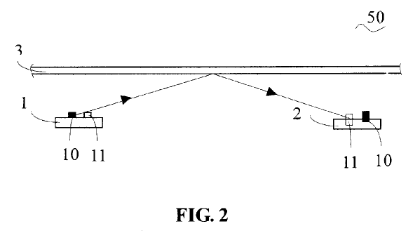

Referring to FIG. 2, shown here is a system for transmitting the IR signal between ICs. The system includes an apparatus 50. The apparatus 50 is configured with an enclosure 3. The apparatus 50 further has two ICs, i.e., IC 1 and IC 2, assembled thereto. As described above, the IC 1 has the IR emitter 10 and the IR receiver 20. If the IC 1 is triggered to send the signal to the IC 2, the IC 1 generates the command with the micro-processor 13, encodes the command into the IR signal by the encoder/decoder 12, and sends out the IR signal through the IR emitter 10. The IR signal is reflected by the enclosure 3 and reaches the IC 2. The IC 2 receives the IR signal by the IR receiver 11, decodes the IR signal into the command by the encoder/decoder 12, and executes the command by the micro-processor 13.

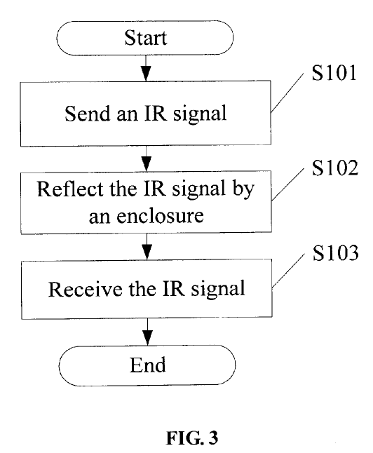

FIG. 3 shows a method for transmitting the IR signal between ICs by utilizing the IC of FIG. 1 and the system of FIG. 2. In step S101, the micro-processor 13 of the IC 1 generates the command. The encoder/decoder 12 encodes the command into the IR signal. The IR emitter 10 sends out the IR signal. In step S102, the IR signal is reflected by the enclosure 3 and reaches the IC 2. In step S103, the IR receiver 11 of the IC 2 receives the IR signal. The encoder/decoder 12 of the IC 2 decodes the IR signal into the command. The micro-processor 13 of the IC 2 executes the command. In using the method mentioned above, the IC 1 and the IC 2 can communicate with each other.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A system for transmitting a signal between integrated circuits, the system comprising:
an apparatus configured with an enclosure;
a first integrated circuit configured with an infrared emitter;
a second integrated circuit configured with an infrared receiver;
wherein the first integrated circuit and the second integrated circuit are assembled in the apparatus, the first integrated circuit encodes a command into an infrared signal and sends the infrared signal through the infrared emitter thereof, the second integrated circuit receives the infrared signal through the infrared receiver thereof and decodes the infrared signal into the command.

2. The system as claimed in claim 1, wherein the infrared signal is reflected by the enclosure and reaches the infrared receiver of the second integrated circuit.

3. The system as claimed in claim 2, wherein each integrated circuit further provides a micro-processor and an encoder/decoder.

4. The system as claimed in claim 3, wherein the micro-processor of the first integrated circuit generates the command.

5. The system as claimed in claim 3, wherein the encoder/decoder of the first integrated circuit encodes the command into the infrared signal.

6. The system as claimed in claim 3, wherein the encoder/decoder of the second integrated circuit decodes the infrared signal into a command.

7. The system as claimed in claim 3, wherein the micro-processor of the second integrated circuit executes the command.

8. A method for transmitting a signal between integrated circuits, the method comprising steps of:
providing an apparatus configured with an enclosure, a first integrated circuit configured with an infrared emitter, and a second integrated circuit configured with an infrared receiver, wherein the first integrated circuit and the second integrated circuit are assembled in the apparatus;
encoding a command into an infrared signal by the first integrated circuit, and sending the infrared signal by the infrared emitter;
receiving the infrared signal by the infrared receiver, and decoding the infrared signal into the command by the second integrated circuit.

9. The method as claimed in claim 8, further comprising a step of reflecting the infrared signal by the enclosure.

10. The method as claimed in claim 8, wherein each integrated circuit provides a micro-processor and an encoder/decoder.

11. The method as claimed in claim 10, further comprising a step of generating the command.

12. The method as claimed in claim 10, further comprising a step of encoding the command into the infrared signal.

13. The method as claimed in claim 10, further comprising a step of decoding the infrared signal into the command.

14. The method as claimed in claim 10, further comprising a step of executing the command.
